(19) United States
(12) Patent Application Publication
(10) Pub. No.: US 2017/0193264 A1
(43) Pub. Date: Jul. 6, 2017

(54) TRACKPAD SEMICONDUCTOR PACKAGE OF SMART DEVICE AND MANUFACTURING METHOD OF SAME

(71) Applicant: HANA MICRON INC., Asan-si (KR)

(72) Inventor: Hyun Joo KIM, Yongin-si (KR)

(73) Assignee: HANA MICRON INC., Asan-si (KR)

(21) Appl. No.: 15/283,687

(22) Filed: Oct. 3, 2016

(30) Foreign Application Priority Data
Jan. 6, 2016 (KR) 10-2016-0001656

(51) Int. Cl. G06K 9/00; H01L 21/56; G06F 3/0354; H01L 23/31; H01L 23/10; H01L 23/00; H01L 21/48

(52) U.S. Cl. CPC G06K 9/0002; H01L 24/83; H01L 24/85; H01L 24/92; H01L 21/565; H01L 21/4803; H01L 24/48; H01L 24/32; H01L 24/73; H01L 23/3121; H01L 23/10; G06F 3/03547; H01L 2924/1433; H01L 2924/146; H01L 2224/32225; H01L 2224/48106; H01L 2224/48227; H01L 2224/73265; H01L 2224/92247

(57) ABSTRACT

A trackpad semiconductor package according to the present invention includes a printed circuit board (PCB), a trackpad device stacked on the PCB, a conductive wire configured to connect the PCB and the trackpad device, a glass assembly directly attached to the trackpad device using a die attach film, and an epoxy molding compound (EMC) mold configured to protect a partial region of the trackpad device that is not covered by the glass assembly and the conductive wire. According to the present invention, a sensing sensitivity is greatly improved.

### CROSS-REFERENCE TO RELATED APPLICATION

This application claims priority to and the benefit of Korean Patent Application No. 2016-0001656, filed on Jan. 6, 2016, the disclosure of which is incorporated herein by reference in its entirety.

### BACKGROUND

1. Field of the Invention

The present invention relates to a manufacturing method of a trackpad semiconductor package of a smart device for fingerprint recognition, and more particularly, to a manufacturing method of a trackpad semiconductor package in which a cover glass is mounted on a trackpad device for fingerprint recognition and is directly attached to the trackpad device to cover a sensing region of the trackpad device, and an epoxy molding compound (EMC) mold processing is performed on a non-sensing region excluding a glass assembly.

In addition, the present invention also relates to a trackpad semiconductor package device for fingerprint recognition used for a smart device, and more particularly, to a trackpad semiconductor package of a smart device for fingerprint recognition in which a trackpad device is mounted on a printed circuit board (PCB), glass processing is performed to protect the trackpad device, and EMC mold processing is performed at the same time and because a top surface of the trackpad is divided into a portion in which the glass cover processing is performed and a portion in which the mold cover processing is preformed, a sensing region in which the glass cover processing is performed includes at least a sensing portion of the trackpad device, and a non-sensing region in which the mold cover processing is performed includes an application specific integrated circuit (ASIC) of the trackpad and a conductive wire.

2. Discussion of Related Art

Generally, a sensor for fingerprint recognition is a sensor which senses a human fingerprint and is recently widely used as a device for strengthening security in a portable electronic device such as a handheld phone or tablet personal computer (PC). That is, data stored in the portable electronic device may be protected and a security breach may be prevented by making a user obtain registration or authentication through the sensor for fingerprint recognition.

Recently, the sensor for fingerprint recognition has been gradually required as a general input device, and for instance, a navigation function which operates a pointer such as a cursor is also integrated in the fingerprint recognition sensor in a smart device. In addition, a switching function, which receives information from the user, is also integrated in the sensor for fingerprint recognition. Moreover, the sensor for fingerprint recognition is not limited to a range of fingerprint recognition and may also include various sensing functions.

Referring to FIG. 1, a trackpad package (10) according to a conventional technique includes a printed circuit board (PCB, 12), a trackpad device (16) stacked on the PCB (12) using an adhesive (14), a conductive wire (18) which connects the PCB (12) and the trackpad device (16), an epoxy molding compound (EMC) mold (20) which protects the trackpad device (16) and the conductive wire (18), and a glass assembly (30) which is attached to the EMC mold (20) using a bonding tape (30c) and in which a color coating film (30b) is formed in a cover glass (30a).

A clearance (h1) between a top surface of the trackpad device (16) and a top surface of the EMC mold (20) is a level of 150 um, and is a factor which reduces a degree of sensing of a sensor. Accordingly, the clearance should be minimized by decreasing the thickness of the EMC mold (20) with which the trackpad device (16) is coated.

However, there is a certain limitation in minimizing the clearance due to the conductive wire (18) which connects the PCB 12 and the trackpad device 16, and thus there is a limitation in which the total thickness of the trackpad semiconductor package may not be further decreased due to the clearance.

### PRIOR ART

Patent document 0001: Korean Laid-Open Patent Publication No. 10-2015-0080812

### SUMMARY OF THE INVENTION

The present invention is directed to a trackpad semiconductor package in which a total thickness of the trackpad semiconductor package may be minimized and a manufacturing method of the same.

The present invention is also directed to a trackpad semiconductor package in which a glass assembly is attached to a region away from a conductive bonding wire that connects a printed circuit board (PCB) to a trackpad device and a manufacturing method of the same.

According to an aspect of the present invention, there is provided a manufacturing method of a trackpad semiconductor package, including: preparing a glass assembly; attaching a trackpad device to a PCB; wire-bonding the PCB and the trackpad device; attaching the glass assembly to the trackpad device; and molding an epoxy molding compound (EMC) at a non-sensing region excluding a sensing region to which the glass assembly is attached.

According to another aspect of the present invention, there is provided a trackpad semiconductor package including: a PCB; a trackpad device stacked on the PCB; a conductive wire configured to connect the PCB and the trackpad device; a glass assembly directly attached to the trackpad device using a die attach film (DAF); and an EMC mold configured to protect a partial region of the trackpad device that is not covered by the glass assembly and the conductive wire.

According to still another aspect of the present invention, there is provided a trackpad semiconductor package in which a trackpad device for fingerprint recognition is mounted on a printed circuit board and cover glass processing and EMC mold processing are performed on the trackpad device to protect the trackpad device, the trackpad semiconductor package including: a portion on which the cover glass processing is performed; and a portion on which the EMC mold processing is performed, wherein: the portion on which the cover glass processing is performed corresponds to a sensing region; the portion on which the EMC mold processing is performed corresponds to a non-sensing region; the sensing region includes at least a sensing portion of the trackpad device; and the non-sensing region includes an application specific integrated circuit (ASIC) of the trackpad device.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a cross-sectional view illustrating a configuration of a trackpad semiconductor package according to a conventional technique;

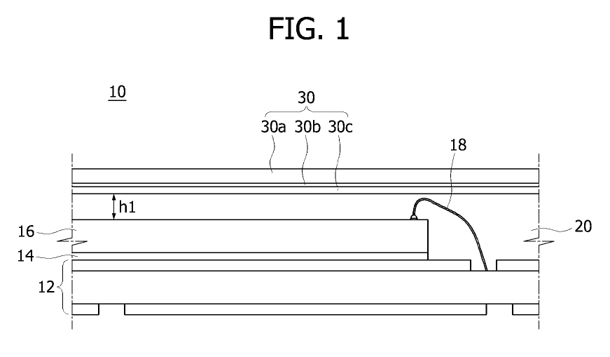

FIG. 2 is a plan view illustrating a configuration of a sensor module for fingerprint recognition in a smart device according to the present invention;

FIG. 3 is a cross-sectional view illustrating a configuration of a trackpad semiconductor package according to one embodiment of the present invention;

FIG. 4 is a cross-sectional view illustrating a configuration of a trackpad semiconductor package according to another embodiment of the present invention;

FIGS. 5A to 5C are cross-sectional views illustrating manufacturing processes of a glass assembly illustrated in FIG. 3;

FIGS. 6A to 6D are cross-sectional views illustrating manufacturing processes of the trackpad semiconductor package illustrated in FIG. 3; and

FIG. 7 is a flow chart of the manufacturing process of the trackpad semiconductor package according to the present invent.

### DETAILED DESCRIPTION OF EXEMPLARY EMBODIMENTS

Advantages and features of the present invention and methods of achieving the same should be clearly understood with reference to the accompanying drawings and the following detailed embodiments. However, the present invention is not limited to the embodiments to be disclosed, but may be implemented in various different forms. The embodiments are provided in order to fully explain the present invention and fully explain the scope of the present invention to those skilled in the art. The scope of the present invention is defined by the appended claims. In the drawings, sizes and relative sizes of layers and regions of the drawings can be exaggerated for clarity of description. The same reference number refers to the same component throughout the specification.

The embodiment described in the specification will be described with reference to plan and cross-sectional views, which are idealized schematic views of the present invention. Accordingly, exemplary views may be changed according to a manufacturing method, tolerance, and/or the like. Accordingly, the present is not limited to illustrated specific forms and also includes changes in forms generated according to a manufacturing process. Accordingly, regions are roughly illustrated in the drawings, and shapes of the regions in the drawings are for exemplifying specific shapes of regions of components and are not limiting to the scope of the invention.

Hereinafter, an exemplary embodiment of the present invention of a trackpad semiconductor package having the above-described configuration will be described in detail with reference to the accompanying drawings.

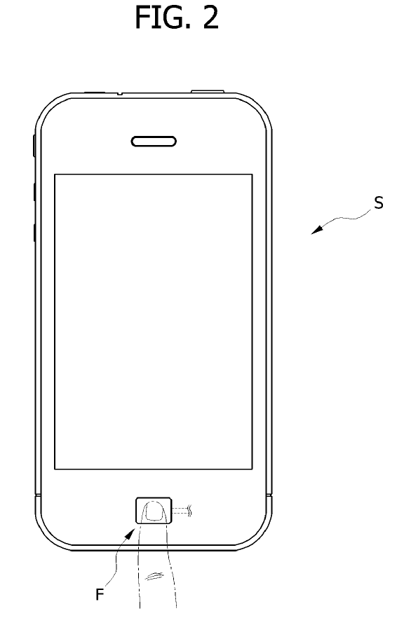

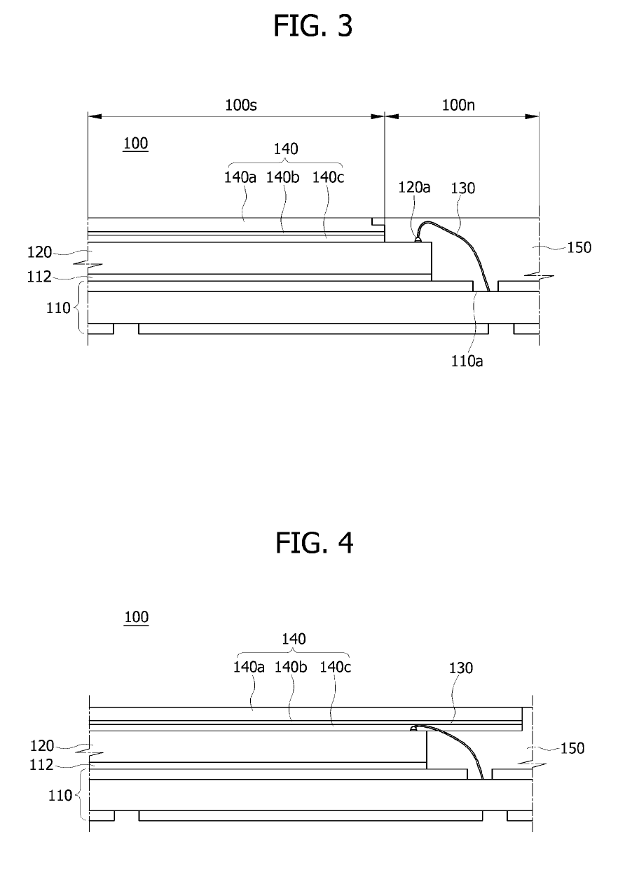

FIG. 2 is a plan view illustrating a sensor module for fingerprint recognition in a smart device according to the present invention, and FIG. 3 is a cross-sectional view illustrating a configuration of a trackpad semiconductor package applied to the sensor module for fingerprint recognition in FIG. 2.

Referring to FIG. 2, a sensor module F for fingerprint recognition may be mounted on a button at a lower portion of a front surface of a smart device S. The fingerprint recognition sensor module F may include a trackpad package 100 for fingerprint recognition, a connecting unit (for instance, a flexible printed circuit board (PCB) cable) that supports the package 100 and connects the package 100 and a main body of the smart device S and the like. Specifically, a home dome button may be installed at a lower portion of the trackpad package 100 for fingerprint recognition according to a specification of the above-described smart device S.

Such a smart device S may include a smart phone, a personal digital assistant (PDA), a handheld personal computer (PC), a mobile phone, and any kind of other electronic device as long as it is a smart device which has similar functions thereof and is possible to carry.

The trackpad package for fingerprint recognition may be applied to the sensor module F for fingerprint recognition in the smart device S.

Referring to FIG. 3, the trackpad semiconductor package 100 according to the present invention includes a PCB 110, a trackpad device 120 stacked on the PCB 110 using an adhesive 112, a conductive wire 130 that electrically connects the PCB 110 and the trackpad device 120, a glass assembly 140 directly attached to the trackpad device 120 using a die attach film (DAF), and an epoxy molding compound (EMC) mold 150 that protects the trackpad device 120 not covered by the glass assembly 140 and the conductive wire 130.

The PCB 110 may all include flexible and rigid boards. The PCB 110 may have interconnection patterns (not shown) formed therein to electrically connect the trackpad device 120 to outside devices, and may have bumps and the like formed at a lower portion thereof using a surface mounting technology (SMT). Such a PCB 110 may be coupled to the above-described connecting unit of the module F or may be a connecting device itself.

Although not illustrated in the drawings, the trackpad device 120 may include a sensing portion that detects an electric signal generated by a fingerprint touch and an application specific integrated circuit (ASIC) that processes the electronic signal. The sensing portion may include a transmitting portion that transmits a radio frequency (RF) signal and a receiving portion that receives a sensor signal. Accordingly, the ASIC may be mounted inside the trackpad device 120, and the sensing portion may be mounted on the trackpad device 120. Such a trackpad device 120 is a semiconductor device for fingerprint recognition, and is not specifically limited thereto.

The trackpad semiconductor package 100 for fingerprint recognition according to the present invention may detect static electricity according to a shape of a fingerprint, and may perform fingerprint authentication using the static electricity as an input signal. For example, since a finger has a fingerprint that is formed with a combination of ridges and valleys, shape information of the ridges and valleys is output using a difference of electrostatic capacity due to roughness (height differences of the ridges and valleys), and fingerprint authentication may be performed by imaging the shape information or comparing the shape information with reference information.

The adhesive 112 is an anisotropic conductive film (ACF) or may include an anisotropic conductive adhesive (ACA). Alternatively, a non-conductive adhesive (NCA) or non-conductive film (NCF) may be used as the adhesive 112. For example, the trackpad device 120 may be electrically connected to the PCB 110 by flip-chip bonding. Here, the ACF or ACA may connect the flip-chip bonding. When the trackpad device 120 is electrically connected to the PCB 110 by wire bonding, the trackpad device 120 may be attached to the PCB 110 by the NCA or NCR

The conductive wire 130 electrically connects a PCB pad 110a on a top surface of the PCB 110 and a chip pad 120a on the trackpad device 120.

The glass assembly 140 includes a color coating film 140b with which one surface of a cover glass 140a is color-coated. The above-described 140c (DAF) is formed on one surface of the color coating film 140b.

The color coating film 140b may include a color film and a protective film. The color film may be attached to, or a color ink may be printed on, such a color film. The color film is formed in the above-described way, and thus various colors may be implemented.

The glass assembly 140 may include a sapphire or reinforced cover glass 140a. Irregularity processing may be performed on a top surface of the cover glass 140a for tactility as necessary. A size of the cover glass 140a may be substantially the same as that of the color coating film 140b. When the trackpad semiconductor package 100 according to the present invention is used for fingerprint authentication in a smart device (for instance, a smart phone), the cover glass 140a may be in a circular or elliptical shape.

Because the EMC mold 150 is not directly in contact with the glass assembly 140 and no mold is provided between the sensing portion of the trackpad device 120 and the color coating film 140b, sensing sensitivity of the sensing portion is increased. In addition, because a bonding process for the glass assembly 140 is performed before a process for the EMC mold 150, a process for the trackpad semiconductor package 100 is completed by the process for the EMC mold 150, and thus the process for the trackpad semiconductor package 100 is simplified.

As described above, the EMC mold 150 is needed to protect the conductive wire 130, and the conductive wire 130, the chip pad 120a to which one end of the conductive wire 130 is connected, and the PCB pad 110a to which the other end of the conductive wire 130 is connected have to be covered. Thus, the EMC mold 150 protects a side surface of the trackpad device 120.

The trackpad semiconductor package 100 according to the present invention may be divided into a portion on which glass processing is performed and a portion on which mold processing is performed when viewed from the top surface thereof. The portion on which the mold processing is performed corresponds to a non-sensing region 100s and the portion on which the glass processing is performed corresponds to a sensing region 100n.

Such a sensing region 100s includes at least the sensing portion of the trackpad device 120. The non-sensing region 100n includes at least the conductive wire 130, the chip pad 120a to which one end of the conductive wire 130 is connected, and the PCB pad 100a to which the other end of the conductive wire 130 is connected. The non-sensing region 100n may further include the ASIC of the trackpad device 120.

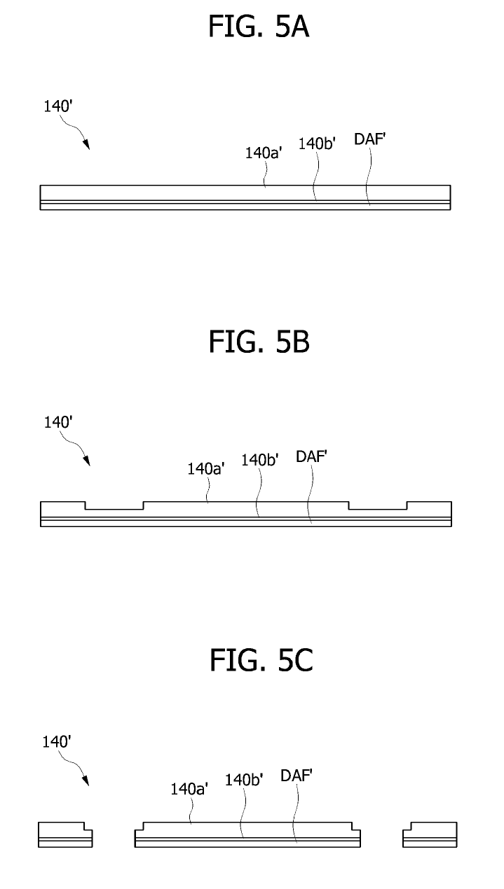

Referring to FIG. 4, a trackpad semiconductor package 100 for fingerprint recognition according to another embodiment of the present invention includes a PCB 110, a trackpad device 120 stacked on the PCB 110 using an adhesive 112, a conductive wire 130 that electrically connects the PCB 110 and the trackpad device 120 using a chip on wire bonding technique, a glass assembly 140 directly attached to the trackpad device 120 using a DAF, and an EMC mold 150 that covers a partial region of the PCB 110 that is not covered by the glass assembly 140.

The glass assembly 140 extends to a region at which the conductive wire 130 is bonded. In the trackpad semiconductor package 100 illustrated in FIG. 3, because the glass assembly 140 is installed at a region away from the conductive wire 130 that connects the PCB 110 and the trackpad device 120, an area with which the trackpad device 120 is covered may have a substantial limitation. However, in the trackpad semiconductor package 100 illustrated in FIG. 4, because the PCB 110 and the trackpad device 120 are connected using the chip on wire bonding technique, the glass assembly 140 may be installed without being away from the conductive wire 130.

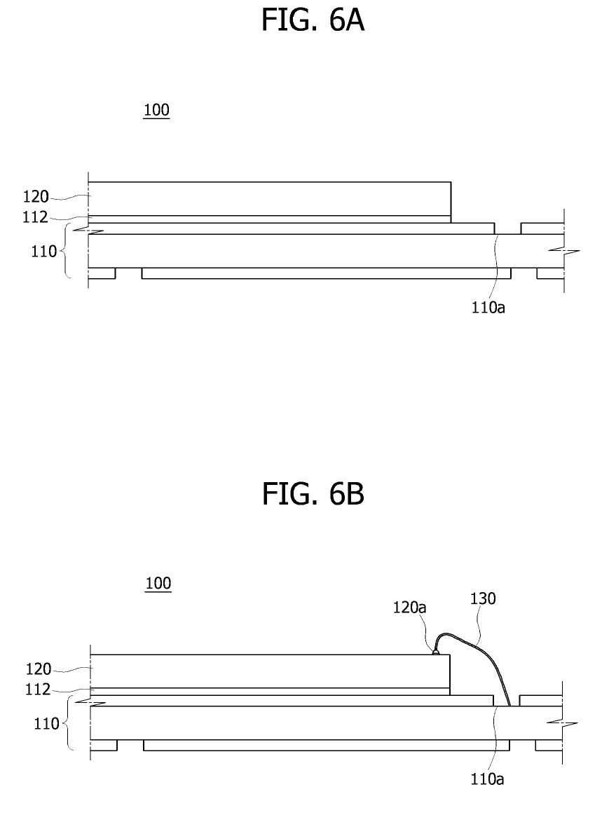

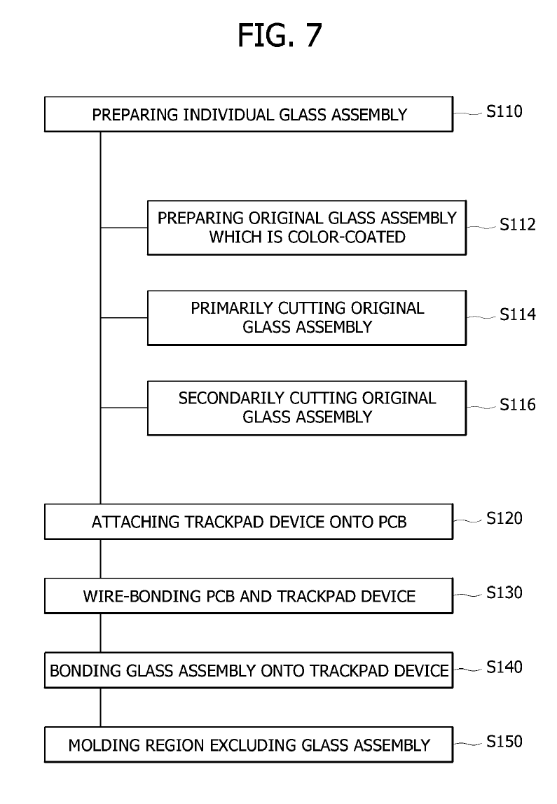

Hereinafter, a manufacturing method of a trackpad semiconductor package according to the present invention will be described with reference to FIGS. 5A to 7.

Preparing an individual glass assembly (S110)

Preparing an original glass assembly to be color-coated (S112)

Referring to FIG. 5A, first, one surface of an original glass 140a′ is color-coated. Second, a DAF is attached to one surface of a color coating film 140b′. Laminating is performed to integrally couple the glass 140a′ and the DAF.

A singulation process in which the original glass assembly 140′ is cut and an individual glass assembly 140 is manufactured is performed.

Primarily cutting the original glass assembly which is color-coated (S114)

Referring to FIG. 5B, a part of the original glass 140a′ is sawed using a blade and the part of the glass is removed. Here, the original glass 140a′ may be sawed using a wide blade having a first width.

Secondarily cutting the primarily cut original glass assembly (S116)

Referring to FIG. 5C, the original glass assembly 140′ is secondarily sawed using a blade and all of the color coating film 140b′ and the DAF are removed. Here, the original glass assembly 140′ is sawed using a narrow blade having a second width narrower than the first width.

The reason why steps are provided on the cover glass 140a of the glass assembly 140 is to make the glass assembly 140 not to arbitrarily leave a mold after an assembly process.

Accordingly, a part of the cover glass 140a′ is removed to have the first width through the primary cutting, and the remaining cover glass 140a′, the color coating film 140b′, and the DAF are removed to have the second width through the secondary cutting, and thus the original glass assembly 140′ may be separated as the individual glass assembly 140.

Attaching a trackpad device onto a PCB (S120)

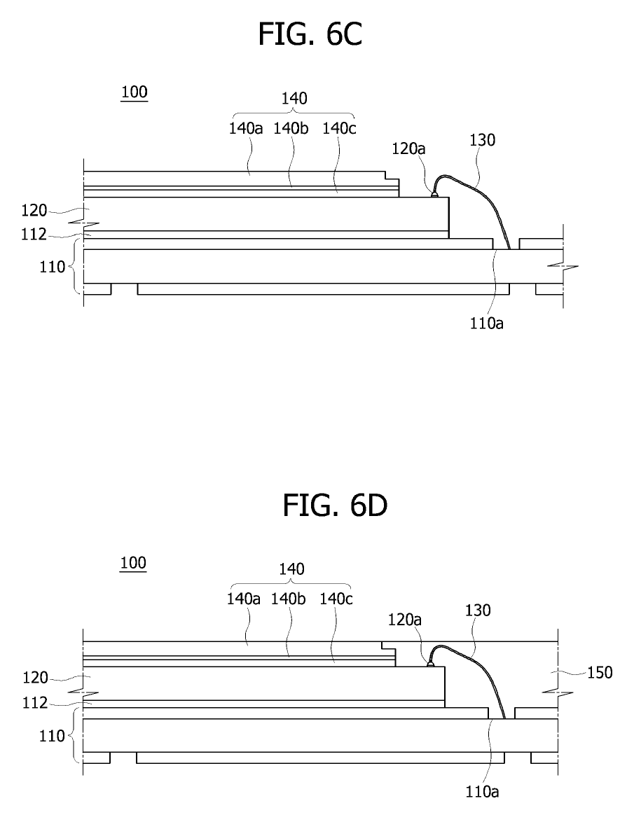

Referring to FIG. 6A, the trackpad device 120 is mounted on the PCB 110 using the adhesive 112. The PCB pad 120a is formed on the PCB 110, and the trackpad device 120 is mounted not to cover the PCB pad 120a. When the trackpad device 120 is connected by wire bonding, the trackpad device 120 may be attached using the adhesive 112 which is not conductive, and when the trackpad device 120 is connected by flip chip bonding, the anisotropic adhesive 112 may be used.

Wire-bonding the PCB and the trackpad device (S130)

Referring to FIG. 6B, a bonding process in which one end of the conductive wire 130 is connected to the chip pad 120a and the other end of the conductive wire 130 is connected to the PCB pad 110a is performed.

Bonding the glass assembly to the trackpad device (S140)

Referring to FIG. 6C, the glass assembly 140 is attached onto the trackpad device 120 using the DAF. The glass assembly 140 is attached to a region excluding a region in which the chip pad 120a of the trackpad device 120 is disposed. The glass assembly 140 is assembled at a region corresponding to a sensing portion of the trackpad device 120.

Molding a region excluding the glass assembly (S150)

Referring to FIG. 6D, the EMC mold 150 is applied on the trackpad device 120 and the PCB 110 excluding the region at which the glass assembly 140 is attached. Specifically, the molding process is performed at a region excluding the sensing portion of the glass assembly 140 to protect the conductive wire 130 that connects the trackpad device 120 and the PCB 110.

As described above, the following effects may be expected according to a configuration of the present invention.

First, because a glass assembly is attached to a region away from a wire bonding region, there is no reason to interpose an EMC mold between the glass assembly and a trackpad device. Accordingly, a factor that reduces a sensing sensitivity of the trackpad is essentially removed, and thus the sensing sensitivity can be substantially improved.

Second, the sensing sensitivity can be improved because a sensing region and a non-sensing region are divided and glass processing and mold processing are respectively performed thereon, a manufacturing cost can be decreased because the mold processing is not performed at a region in which the mold processing is not necessary, and an overall yield can be increased because the number of processes is decreased.

As illustrated above, the present invention has a technological scope in that a cover glass is mounted on a trackpad device and is installed to cover a sensing portion of the trackpad device, and an EMC molding process is performed at a non-sensing region excluding the cover glass. In the scope of the present invention, the embodiments may be variously modified by those skilled in the art.

What is claimed is:

1. A manufacturing method of a trackpad semiconductor package comprising:
preparing a glass assembly;
attaching a trackpad device onto a printed circuit board (PCB);
wire-bonding the PCB and the trackpad device;
attaching the glass assembly onto the trackpad device; and
molding an epoxy molding compound (EMC) at a non-sensing region excluding a sensing region to which the glass assembly is attached.

2. The manufacturing method of claim 1, wherein:
the non-sensing region is a region including at least a wire, a chip pad of the trackpad device to which one end of the wire is connected, and a PCB pad of the PCB to which the other end of the wire is connected; and
the sensing region is a region including at least a sensing portion of the trackpad device.

3. The manufacturing method of claim 2, wherein:
the non-sensing region further includes an application specific integrated circuit (ASIC) of the trackpad device;
the sensing region is processed by the attaching of the glass assembly; and
the non-sensing region is processed by the molding of the EMC.

4. The manufacturing method of claim 1, wherein the preparing of the glass assembly includes:
preparing an original glass assembly which is color-coated;
primarily cutting the original glass assembly; and
secondarily cutting the primarily cut original glass assembly to separate the primarily cut original glass assembly into the glass assembly.

5. The manufacturing method of claim 4, wherein:
the original glass assembly includes a color coating film on one surface of the cover glass and a die attach film (DAF) on one surface of the color coating film;
the primary cutting removes a part of the cover glass using a wide blade having a first width; and
the secondary cutting removes the remaining cover glass, the color coating film, and the DAF using a narrow blade having a second width narrower than the first width.

6. A trackpad semiconductor package comprising:
a printed circuit board (PCB);
a trackpad device stacked on the PCB;
a conductive wire configured to connect the PCB and the trackpad device;
a glass assembly directly attached to the trackpad device using a die attach film (DAF); and
an epoxy molding compound (EMC) mold configured to protect a partial region of the trackpad device that is not covered by the glass assembly and the conductive wire.

7. The trackpad semiconductor package of claim 6, wherein:
the trackpad device includes a sensing portion that detects an electrical signal generated by a fingerprint touch and an application specific integrated circuit (ASIC) that processes the electrical signal; and
the conductive wire is connected to the ASIC.

8. The trackpad semiconductor package of claim 7, wherein the EMC mold does not cover the sensing portion.

9. The trackpad semiconductor package of claim 7, wherein:
the glass assembly covers at least the sensing portion; and
the sensing portion is disposed above the trackpad device and includes a transmitting portion configured to transmit a radio frequency (RF) signal and a receiving portion configured to receive a sensor signal.

10. The trackpad semiconductor package of claim 7, wherein the glass assembly includes a cover glass and a color coating film that is formed on one surface of the cover glass.

11. The trackpad semiconductor package of claim 10, wherein the cover glass is formed of sapphire glass or reinforced glass.

12. A trackpad semiconductor package in which a trackpad device for fingerprint recognition is mounted on a printed circuit board (PCB) and cover glass processing and an epoxy molding compound (EMC) mold processing are performed on the trackpad device to protect the trackpad device, the trackpad semiconductor package comprising:
a portion on which the cover glass processing is performed; and
a portion on which the EMC mold processing is performed,
wherein:
the portion on which the cover glass processing is performed corresponds to a sensing region;
the portion on which the EMC mold processing is performed corresponds to a non-sensing region;
the sensing region includes at least a sensing portion of the trackpad device; and
the non-sensing region includes an application specific integrated circuit (ASIC) of the trackpad device.

13. A trackpad semiconductor package comprising:
a printed circuit board (PCB);
a trackpad device stacked on the PCB through an adhesive film and including a sensing portion configured to detect an electrical signal generated by a fingerprint touch and an application specific integrated circuit (ASIC) configured to process the electrical signal;
a conductive wire configured to connect the PCB and the trackpad device;
a glass assembly attached to the trackpad device using a die attach film (DAF) and including a color coating film between the DAF and the glass assembly; and
an epoxy molding compound (EMC) mold configured to protect a partial region of the trackpad device and the conductive wire,
wherein the glass assembly covers a total region of the sensing portion and the ASIC of the trackpad device.

14. The trackpad semiconductor package of claim 13, wherein:
one end of the conductive wire is connected to a chip pad formed on the trackpad device and the other end is connected to a PCB pad formed on the PCB; and
the conductive wire is formed to pass through the EMC mold and the DAF.
